(19) United States
(12) Patent Application Publication
(10) Pub. No.: US 2013/0126845 A1
(43) Pub. Date: May 23, 2013

(54) ORGANIC ELECTROLUMINESCENCE DEVICE

(71) Applicant: Toppan Printing Co., Ltd., Tokyo (JP)

(72) Inventors: Noriko Morikawa, Tokyo (JP); Eiichi Kitazume, Tokyo (JP)

(73) Assignee: TOPPAN PRINTING CO., LTD., Tokyo (JP)

(21) Appl. No.: 13/741,165

(22) Filed: Jan. 14, 2013

Related U.S. Application Data
(63) Continuation of application No. PCT/JP2011/065351, filed on Jul. 5, 2011.

(30) Foreign Application Priority Data
Jul. 21, 2010 (JP) 2010-164218

(51) Int. Cl. H01L 51/50

(52) U.S. Cl. CPC H01L 51/5012
USPC 257/40

(57) ABSTRACT

A display equipment 200 containing an organic EL device is constituted by containing a substrate 101 having thereon a first electrode 102 provided for respective pixels, a partition wall 203 partitioning the first electrode 102 among the pixels, a hole transporting layer 104 formed above the first electrode 102, a light emitting layer 106 formed on the hole transporting layer 104, a second electrode 107 formed to cover the entire surface of the light emitting layer 106, and a sealing member 208 in contact with the substrate 101 to cover the first electrode 102, the partition wall 203, a light emitting medium layer 109 containing the hole transporting layer 104 and the light emitting layer 106, and the second electrode 107.

### CROSS REFERENCE TO RELATED APPLICATION

This application is a continuation of International Application No. PCT/JP2011/065351, filed on Jul. 5, 2011 the entire contents of which are incorporated herein by reference.

### TECHNICAL FIELD

The present invention relates to an organic electroluminescence display equipment (which may be hereinafter referred to as an organic EL display equipment) containing arranged therein an organic electroluminescence device (which may be hereinafter referred to as an organic EL device) utilizing an organic electroluminescence phenomenon. More specifically, the invention relates to an organic electroluminescence display equipment that has a simple structure, has new functions imparted by a simple process to functional layers constituting the organic EL devices, and has a improved efficiency and a decreased operation voltage.

### BACKGROUND ART

In an organic EL device, an electroconductive light emitter is applied with a voltage to recombine the injected electrons and holes, and light is emitted from the light emitter on the recombination. In general, the organic EL device is constituted by providing an anode formed of a transparent electrode, such as ITO, on a translucent substrate, and accumulating sequentially thereon a light emitting layer and a cathode.

The electrodes may be accumulated directly on both the surfaces of the light emitting layer, as described above, but such structures may be often employed that a hole injection layer, a hole transporting layer or both of them are provided between the anode and the light emitting layer, and an electron injection layer, an electron transporting layer or both of them are provided between the cathode and the light emitting layer for the purpose of increasing light emitting efficiency, or the like. All the layers including the hole injection layer between the electrodes are referred to as a light emitting medium layer.

The organic EL devices are classified into several groups depending on the materials used in the light emitting layer. One of the representative groups is a device using a low molecular weight organic compound in the light emitting layer, and the device is produced mainly by vacuum deposition. Another one of them is a polymer organic EL device using a polymer compound in the light emitting layer. In the polymer organic EL device, the layers may be formed as a film by wet process by using solutions each containing a material constituting the functional layer dissolved in a solvent. Examples of the film forming method by wet process include a spin coating method, an ink-jet method and a printing method, and all the methods do not require vacuum, and thus the methods are advantageous in energy cost and material cost, and are useful for patterning in a large area.

Various techniques have been proposed for increasing the luminance and decreasing the operation voltage of an organic EL device, and one of them is a method of using the respective functional layers as a mixture. For example, Patent Document 1 discloses that a low molecular weight organic EL device using a mixture of a light emitting material and a charge transporting material as a material of a light emitting layer, and a concentration gradient is provided in the light emitting layer, and Patent Document 2 discloses that a polymer and an electron transporting low molecular weight compound are mixed to use the polymer as a binder material, thereby enhancing the film forming property.

### PRIOR ART LITERATURE

### Patent Documents

Patent Document 1: JP-A-2004-241188
Patent Document 2: JP-A-11-251065

### SUMMARY OF THE INVENTION

In a polymer organic EL device that is produced by an ordinary wet method, only one kind of a polymer compound is generally formed into an ink and coated. Accordingly, for emitting light with an increased luminance at a reduced operation voltage, it is necessary to develop the material therefor itself, which requires considerably large cost and time for development.

The invention has been made under the circumstances, and an object of the invention is to provide an organic EL display equipment that has an increased luminance and a decreased operation voltage.

### Means For Solving The Problems

A first invention proposed for solving the problems is an organic electroluminescence device containing a substrate having thereon a first electrode, a light emitting medium layer containing at least a light emitting layer, and a second electrode on the light emitting medium layer, at least one layer of the light emitting medium layer being formed with a mixed ink containing a first polymer compound and a second polymer compound that has a larger carrier mobility than the first polymer compound, the mixed ink having a weight ratio of the second polymer compound to the first polymer compound of 30% by weight or less, and by mixing the second polymer compound with the first polymer compound, the device having a light emitting voltage that is lower than a case where the at least one layer of the light emitting medium layer is formed with an ink containing only the first polymer compound.

A second invention is the organic electroluminescence display equipment according to the first invention, wherein the second polymer compound has a hole mobility of more than 1.0×10⁻⁴ (cm²/Vs).

A third invention is the organic electroluminescence display equipment according to the second invention, wherein the second polymer compound has an energy gap that is larger than an energy gap of the first polymer compound.

A fourth invention is the organic electroluminescence display equipment according to the third invention, wherein the at least one layer of the light emitting medium layer is the light emitting layer.

### Advantages of the Invention

According to the invention, two or more kinds of polymer materials having different carrier mobilities are mixed, and the combination and the mixing ratio of the materials to be mixed are controlled, whereby new functions may be imparted conveniently to the respective functional layers by controlling the combination and the mixing ratio of the materials to be mixed without new synthesis of materials, thereby increasing the luminance and decreasing the operation voltage conveniently.

### BRIEF DESCRIPTION OF THE DRAWINGS

FIG. 1 is a schematic cross sectional view of an organic EL display equipment of the invention.

FIG. 2 is a schematic cross sectional view showing another example of an organic EL display equipment of the invention.

FIG. 3 is a schematic plane view showing electrode configuration of a passive organic EL display equipment.

FIG. 4 includes schematic cross sectional views showing laminate structures of organic EL devices of the invention, in which (A) is a schematic cross sectional view of a bottom emission organic EL device, and (B) is a schematic cross sectional view of a top emission organic EL device.

### EMBODIMENT FOR CARRYING OUT THE INVENTION

Embodiments of the invention will be described with reference to the drawings. The drawings referred in the following description for the embodiments are for describing the constitution of the invention, and the sizes, thicknesses and dimensional ratios of the members shown in the drawings do not directly show the embodiments themselves.

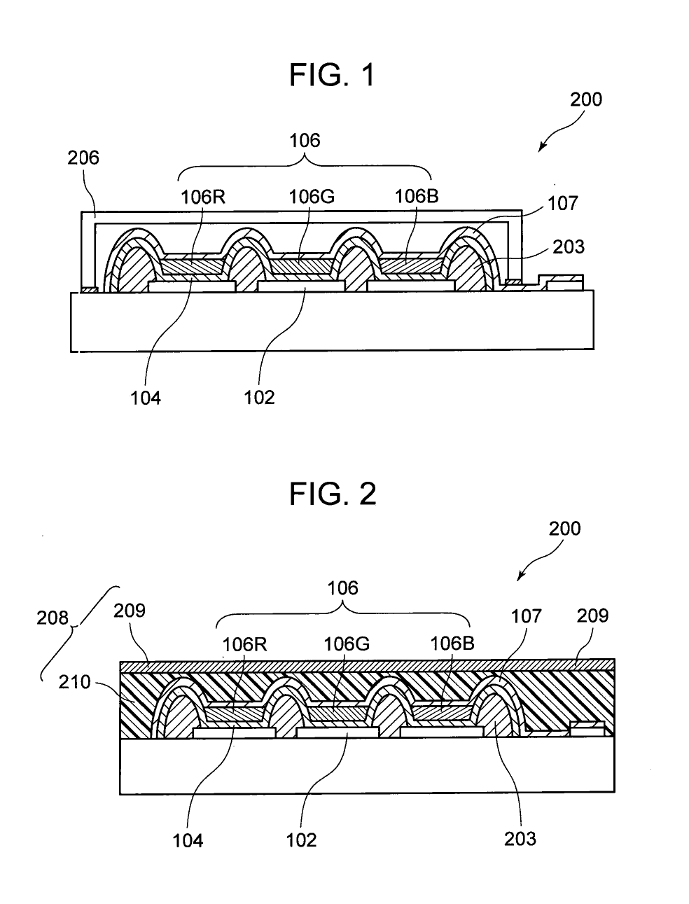

FIG. 1 is a cross sectional view showing a structure of an organic EL display equipment for describing an embodiment of the invention. The display equipment 200 using an organic EL device of an embodiment of the invention shown in FIG. 1 has a substrate 101 having provided thereon a first electrode (anode) 102 that is provided for each of pixels, a partition wall 203 that partitions the first electrode 102 between pixels, a hole transporting layer 104 that is formed above the first electrode 102, a light emitting layer 106 that is formed on the hole transporting layer 104, a second electrode (cathode) 107 that is formed on the light emitting layer 106 to cover the entire surface thereof, and a sealing member 208 that is in contact with the substrate 101 and covers the first electrode 102, the partition wall 203, a light emitting medium layer 109 containing the hole transporting layer 104 and the light emitting layer 106, and the second electrode 107. Examples of the sealing member 208 include a sealing cap 206 that covers the organic EL device with an inert gas filled inside the sealing cap 206 as shown in FIG. 1, and a sealing material 209 adhered through a resin layer 210 as shown in FIG. 2.

A switching device (thin film transistor) for controlling the respective pixels is connected to the first electrode 102, but is not shown in the figures. As shown in FIG. 3, a passive matrix organic EL display equipment may be employed, in which a first electrode 102 and a second electrode 107, which are each in a stripe form, are crossed each other, thereby turning on an intended pixel. In the following description, the region where the light emitting medium layer 109 is held between the first electrode 102 and the second electrode 107 is referred to as a light emitting region or an organic EL device, and the entire array of the organic EL devices including the partition wall 203 is referred to as a display region.

The light emitting medium layer 109 herein is a layer that is held between the first electrode (anode) 102 and the second electrode (cathode) 107. In the device shown in FIG. 1, the hole transporting layer 104 and the light emitting layer 106 correspond to the light emitting medium layer 109. In addition, such layers as a hole injection layer, an electron transporting layer and an electron injection layer (all of which are not shown in the figures) may be appropriately added to the light emitting medium layer 109.

In the example shown in FIG. 1, for example, the light emitting medium layer 109 is constituted by the hole transporting layer 104 and the light emitting layer 106, which are accumulated sequentially on the first electrode (anode) 102, the light emitting medium layer 109 may be constituted by two layers, i.e., a hole injection layer (which is not shown in the figures) and the light emitting layer 106. The light emitting medium layer 109 may also have a three-layer structure including a hole injection layer, a hole transporting layer and a light emitting layer, which are sequentially accumulated.

One layer may have functions of plural layers, and for example, such a structure may be employed that the light emitting layer 106 has a hole transporting function. In alternative, such a structure may be employed that is constituted by a hole injection layer and an electron transporting layer, and the interface therebetween emits light.

In the organic EL display equipment of the invention, a mixed ink of two kinds of polymer compounds that have different carrier mobilities is used in at least one layer constituting the light emitting medium layer 109. The layer, in which the mixed ink is used, may be any of the hole injection layer, the hole transporting layer 104 and the light emitting layer 106, and in the case where the mixed ink is used in the light emitting layer 106, the light emitting layer 106 may be enhanced in hole transporting property or enhanced in electron blocking property, and thus the accumulated films including the hole injection layer and the hole transporting layer 104 may be advantageously reduced. Furthermore, the light emitting layer 106 has a lower hole mobility than the other layers, i.e., the hole injection layer and the hole transporting layer 104, and thus the enhancement of the hole transporting property of the light emitting layer 106 largely contributes to the decrease of the operation voltage of the device.

In general, a polymer compound that is used as the light emitting layer 106 has a hole mobility of 1.0×10⁻³ (cm²/Vs) or less. When the hole mobility is in the level, the light emitting drive voltage is high, which increases the electric power consumption of the display, and thus it is necessary to decrease the operation voltage thereof. Accordingly, in this embodiment, the hole mobility (μB) of the polymer compound B, which is mixed with the polymer compound A, is preferably more than 1.0×10⁻⁴ (cm²/Vs) for providing larger decrease of the operation voltage, and more preferably more than 1.0×10⁻³ (cm²/Vs).

The difference between the hole mobility (μA) of the polymer compound A and the hole mobility (μB) of the polymer compound B is preferably 10 times or more and 1,000 times or less, and more preferably 50 times or more and 500 times or less. When the difference is less than 10 times, the enhancement of the hole transporting property may be small, and when it exceeds 1,000 times, the fluctuation in characteristics due to mixing may be increased.

The mixing ratio of the polymer compound A and the polymer compound B is preferably such that the weight ratio of the polymer compound B is preferably 1% by weight or more and 30% by weight or less, and more preferably 1% by weight or more and 15% by weight or less, with respect to the polymer compound A. When the weight ratio exceeds 30% by weight, a too large electric current may flow in the polymer compound A having a small hole mobility to accelerate deterioration of the polymer compound A, which conspicuously reduces the service life. When the weight ratio is less than 1% by weight, the enhancement of the hole transporting property may be disadvantageously small.

In the case where the mixed ink is used in the light emitting layer 106, the energy gap (E_{gB}) of the polymer compound B is preferably larger than the energy gap (E_{gA}) of the polymer compound A. When the energy gap (E_{gB}) of the polymer compound B is smaller than the energy gap (E_{gA}) of the polymer compound A, emitted light from the polymer compound A may be reabsorbed by the polymer compound B, which brings about reduction of the electric current efficiency and change of the chromaticity.

The thickness of the light emitting medium layer 109 may be 1,000 nm or less, and preferably from 50 to 300 nm, as the total light emitting medium layer 109 in both the case where the light emitting medium layer 109 is constituted by the single light emitting layer 106 and the case where the layer has a multilayer structure. When the thickness exceeds 1,000 nm, the drive voltage may be disadvantageously increased.

In the structures of the organic EL display equipment shown in FIGS. 1 and 2, the light emitting layers 106R, 106G and 106B that are formed by patterning the light emitting layer 106 corresponding to light emitting wavelengths for red (R), green (G) and blue (B) are formed with respect to the patterned electrodes, thereby enabling a full color display panel. As other methods than the above, a colorant conversion system using a blue light emitting layer and a colorant conversion layer may be employed, and a structure containing a white EL device provided with a color filter may be employed.

In the organic EL display equipment of the invention, the mixed ink may be used in all the light emitting layers for red (R), green (G) and blue (B) with respect to the patterned electrodes, or the mixed ink may be used in only for one color or two colors.

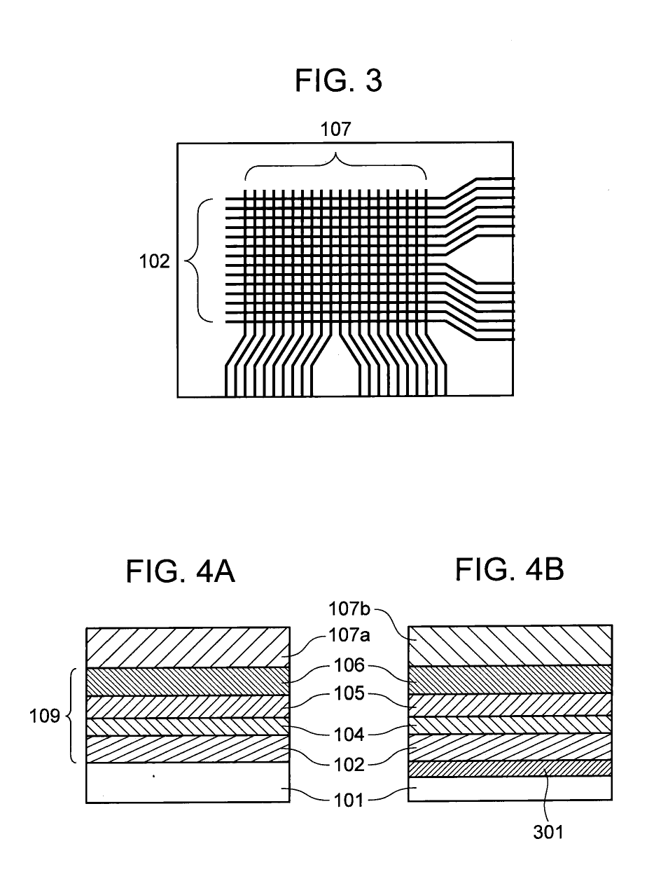

FIGS. 4(A) and 4(B) are cross sectional views of the accumulated portions, i.e., the light emitting regions, of the organic EL device of the invention. FIG. 4(A) shows an example of a bottom emission organic EL device, which contains a substrate 101 having accumulated thereon a first electrode 102, a light emitting layer 106 and a second electrode 107a in this order. When the layers are accumulated in this order, the light emitting medium layer 109 may contain, in addition to the hole transporting layer 104 and the light emitting layer 106, an interlayer 105 and other layers accumulated between the layers. The second electrode 107a is a light impermeable electrode, and by using a material having a large reflectivity, such as a metal, therefor, light radiated toward the side of the second electrode 107a is reflected by the second electrode 107a and radiated to the outside through the first electrode 102, which is a light permeable electrode, thereby providing an enhanced light taking out efficiency.

FIG. 4(B) shows an example of a top emission organic EL device, which contains a substrate 101 having accumulated thereon a reflective layer 301, a first electrode 102, a hole transporting layer 104, an interlayer 105, a light emitting layer 106 and a second electrode 107b in this order. When the layers are accumulated in this order, other layers may be accumulated between the layers. The second electrode 107b is a light permeable electrode, and light radiated toward the side of the first electrode 102 passes through the first electrode 102, reflected by the reflective layer 301 and radiated to the outside through the second electrode 107b. Light radiated toward the side of the second electrode 107b is similarly radiated to the outside through the second electrode 107b. The following description are to be made for the bottom emission organic EL device, but are applied also to the top emission type with a transparent electroconductive film as the second electrode 107b.

The constitutional components and the production method of the invention in the case where a mixed ink is used in the light emitting layer 106 will be described below, but the invention is not limited to the constitution. The light emitting layer 106, which is the mixed ink, may be accumulated after accumulating the interlayer 105 on the hole transporting layer 104, or such a constitution may be employed that the light emitting layer 106 is not coated in a pattern form.

Examples of the material for the substrate 101 include glass, quartz, and a plastic film or sheet, such as polypropylene, polyether sulfone, polycarbonate, cycloolefin polymer, polyarylate, polyamide, polymethyl methacrylate, polyethylene terephthalate and polyethylene naphthalate, and in the case of the top emission organic EL device, examples thereof additionally include a light permeable substrate containing the aforementioned plastic film or sheet having accumulated thereon, in the form of a single layer or in a multilayer structure, a metal oxide, such as silicon oxide and aluminum oxide, a metal fluoride, such as aluminum fluoride and magnesium fluoride, a metal nitride, such as silicon nitride and aluminum nitride, a metal oxynitride, such as silicon oxynitride, or a polymer resin film, such as an acrylic resin, an epoxy resin, a silicone resin and a polyester resin, and a light impermeable substrate, such as a metal foil, sheet or plate of, e.g., aluminum and stainless steel, and a plastic film or sheet having a metal film, such as aluminum, copper, nickel or stainless steel, accumulated thereon. However, the invention is not limited to these materials.

The surface of the display equipment 200 of the embodiment using the organic EL device, from which light is taken out, for the bottom emission type may be the side of the first electrode 102 adjacent to the substrate 101. For the top emission type, it may be the side of the second electrode 107b facing the substrate 101. The substrate 101 formed of these materials is preferably subjected to a moisture proof treatment or a hydrophobic treatment on the entire surfaces or one surface thereof by forming an inorganic film or coating a resin, for preventing water and oxygen from penetrating into the display equipment 200. In particular, for preventing water from penetrating into the light emission medium layer 109, the substrate 101 preferably has a small water content and a small gas permeability coefficient.

The first electrode 102 is formed on the substrate 101, and patterned depending on necessity. The first electrode 102 is partitioned with the partition wall 103 (see FIGS. 1 and 2) to form pixel electrodes corresponding to the subpixeis.

Examples of the material for the first electrode 102 include a metal complex oxide, such as ITO (indium tin complex oxide), IZO (indium zinc complex oxide) and AZO (zinc aluminum complex oxide), a metal material, such as gold and platinum, and a fine particle dispersed film containing fine particles of the metal oxide or the metal material dispersed in an epoxy resin, an acrylic resin or the like, in the form of a single layer or in a multilayer structure. The first electrode 102 may also be formed by a coating and heat-decomposition method, in which a precursor, such as indium octylate or acetone indium, is coated on the substrate and then heat-decomposed to form an oxide.

In the case where the first electrode 102 is used as an anode, a material having a large work function, such as ITO, is preferably selected. In a TFT-driven organic electroluminescence display equipment, a material having a low resistance may be used, and a material having a sheet resistance of 20Ω·sq or less may be preferably used.

Examples of the forming method of the first electrode 102 include known film forming methods, for example, a dry film forming method, such as a resistance heating vapor deposition method, an electron beam vapor deposition method, a reactive vapor deposition method, an ion plating method and a sputtering method, and a wet film forming method, such as an ink jet printing method, a gravure printing method and a screen printing method, which may be selected depending on the material used, and the invention is not limited thereto. The taking out electrode, which is not shown in the figures, may be formed with the same materials in the same process.

Examples of the patterning method of the first electrode 102 include known patterning methods, for example, a mask vapor deposition method, a photolithography method, a wet etching method and a dry etching method, which may be selected depending on the materials and the film forming method.

The first electrode 102 may be subjected to surface activation depending on necessity by a UV treatment, a plasma treatment or the like.

In the case of a top emission type, a reflective layer 301 is preferably formed under the first electrode 102 (see FIG. 4). The material for the reflective layer 301 is preferably a material having a high reflectivity and a low resistance, and examples thereof include a single layer film, a multilayer film or an alloy film containing at least one of Cr, Mo, Al, Ag, Ta, Cu, Ti and Ni, and a film formed of these materials having formed thereon a protective film, such as SiO, SiO₂ or ToO₂. The reflectivity thereof may be 80% or more in terms of an average over the visible light wavelength range, and is preferably 90% or more. The conditions for the reflectivity is not applied to the case where the light emitting medium layer 109 or the first electrode 102 is formed with a light impermeable material.

Examples of the forming method thereof include known film forming methods, for example, a dry film forming method, such as a resistance heating vapor deposition method, an electron beam vapor deposition method, a reactive vapor deposition method, an ion plating method and a sputtering method, and a wet film forming method, such as an ink jet printing method, a gravure printing method and a screen printing method, which may be selected depending on the material used, and the invention is not limited thereto.

Examples of the patterning method of the reflective layer include known patterning methods, for example, a mask vapor deposition method, a photolithography method, a wet etching method and a dry etching method, which may be selected depending on the materials and the film forming method.

As shown in FIGS. 1 and 2, the partition wall 203 may be formed to partition the light emitting regions corresponding to the respective pixels, and in the case where the light emitting medium layer 109 is patterned by a wet coating method, it also functions as a barrier preventing color mixing from occurring on coating in a pattern form for the respective pixels.

The partition wall 203 is preferably formed to cover an edge of the first electrode 102. In general, in the display equipment 200 using an active matrix driven organic EL device, the first electrode 102 is formed for the respective pixels, and the respective pixels occupy an area as large as possible. Accordingly, the partition wall 203 may be formed to cover the edge of the first electrode 102. The most preferred shape of the partition wall 203 is basically a lattice shape that partitions the respective pixel electrodes 102 with the shortest length.

The photosensitive material for forming the partition wall 203 may be a positive resist or a negative resist and may be a commercially available material, and the material necessarily has insulating property. When the partition wall 203 does not have sufficient insulating property, an electric current flows between the pixel electrodes adjacent to each other through the partition wall 203, which may cause display failure. Specific examples thereof include a polyimide series, an acrylic resin series, a novolak resin series and a fluorene series, but the material, is not limited thereto. A light shielding material may be contained in the photosensitive material for enhancing the display quality of the organic EL device.

The photosensitive resin for forming the partition wall 203 may be coated by a known coating method, such as a spin coater, a bar coater, a roll coater, a die coater and a gravure coater. In the process of patternwise exposure and development for forming the partition pattern, the pattern in the partition wall portion may be formed by a known exposing and developing method. The baking thereof may be performed by a known method, such as an oven or a hot plate.

Examples of the patterning method of the partition wall 203 include such a method that a photosensitive resin is coated on the substrate 101, and a prescribed pattern is formed by a photolithography method, but the invention is not limited thereto. The resist and the photosensitive resin may be subjected to a surface treatment, such as plasma irradiation or UV irradiation, depending on necessity.

The thickness of the partition wall 203 is preferably in a range of from 0.5 to 5.0 μm. By providing the partition wall 203 between the pixel electrodes adjacent to each other, the hole transporting ink printed on the respective pixel electrodes is suppressed from spreading, thereby preventing short circuit from occurring at the edge of the first electrode (anode) 102. When the height of the partition wall 203 is too low, occurrence of short circuit may not be prevented, and when the height is too large, the second electrode (cathode) 107 may be broken on forming the second electrode (cathode) 107 orthogonally to the partition wall 203, which may cause display failure.

As a pretreatment of the substrate, a UV treatment, a plasma treatment or the like may be performed. The pretreatment is performed mainly for rinsing the surface of ITO used as an anode and controlling the work function thereof. For injecting holes efficiently to the light emitting medium layer 109, it is preferred that the work function of the light emitting medium layer 109 is close to that of the surface of the first electrode 102. Accordingly, the difference between the work function of the surface of the first electrode 102 after subjecting the surface treatment and the work function of the light emitting medium layer 109 in contact with the first electrode 102 is preferably 0.5 eV or less, and more preferably 0.2 eV or less. ITO has a work function of 4.8 eV before the surface treatment, and in the case where a hole transporting layer 104 and a hole injection layer are formed as the light emitting medium layer 109 on the first electrode 102 as described later, the work function, for example, of molybdenum oxide is 5.5 eV. The difference of the work functions in she initial state is too large, and holes are prevented from being injected due to the high hole injection barrier. Accordingly, the work function of the first electrode 102 may be increased by the surface treatment to be made close to the work function of the hole transporting layer 104.

Examples of the light source for the UV treatment include a low pressure mercury lamp, a high pressure mercury lamp and an excimer lamp, any of which may be used in the invention. In the case where an oxygen plasma treatment is performed, the work function of the first electrode 102 may be controlled to an arbitrary state by controlling the electric power, the pressure and the irradiation time, but it is necessarily controlled delicately since the oxygen plasma treatment may slightly etch the partition wall 203 simultaneously with the surface treatment of the first electrode 102.

The surface of ITO thus oxidized returns to the original state with the lapse of time, and thus the surface treatment of the first electrode 102 is preferably performed immediately before forming the hole transporting layer 104.

The hole injection layer is a layer that has a function of injecting holes from the first electrode (anode) 102, and the hole transporting layer 104 is a layer that has a function of transporting holes to the light emitting layer. These layers may have both the hole injection function and the hole transporting function in some cases, and may be referred to as one of or both of the names depending on the extent of one functions. In the description, the term “hole transporting layer” may include a hole injection layer in some cases.

The hole transporting layer 104 preferably has, as property value thereof, a work function that is equivalent to or higher than the work function of the anode (first electrode 102). This is because holes are injected efficiently from the anode to the light emitting medium layer 109 (the interlayer 105). The work function may be from 4.5 to 6.5 eV while it varies depending on the material of the anode, and in the case where the anode is ITO or IZO, it is preferably from 5.0 to 6.0 eV. In the bottom emission structure, the light taking out efficiency may be decreased when the light transmittance thereof is low since the radiated light is taken out from the side of the first electrode 102, and the light transmittance is preferably 75% or more in terms of an average over the visible light wavelength range, and further 85% or more may be preferably employed.

Examples of the material constituting the hole injection layer and the hole transporting layer 104 include polymer materials, such as polyaniline, polythiophene, polyvinylcarbazole, and a mixture of poly(3,4-ethylenedioxythiophene) and polystyrenesulfonic acid.

In addition, an electroconductive polymer having an electroconductivity of from 1.0×10⁻² to 10⁻⁶ S/cm may be preferably used. The use of a polymer material is preferred since the layer may be formed by a wet method. The material may be used after forming it into a solution or a dispersion by using water or a solvent. In the case where an inorganic material is used as the hole transporting material, examples thereof include Cu₂O, Cr₂O₃, Mn₂O₃, FeOₓ (x: about 0.1), NiO, CoO, Bi₂O₃, SnO₂, ThO₂, Nb₂O₅, Pr₂O₃, Ag₂O, MoO₂, ZnO, TiO₂, V₂O₅, Nb₂O₅, Ta₂O₅, MoO₃, WO₃ and MnO₂.

The hole transporting layer 104 may be formed over the display area at one time by a convenient method, such as a spin coating method, a die coating method, a dip coating method or a slit coating method. On forming the hole transporting layer 104, the hole transporting material may be dissolved in water, an organic solvent or a mixed solvent thereof to form an ink. Examples of the organic solvent used include toluene, xylene, anisole, mesitylene, tetralin, acetone, methyl ethyl ketone, methyl isobutyl ketone, cyclohexanone, methanol, ethanol, isopropyl alcohol, ethyl acetate and butyl acetate. The ink may contain a surfactant, an antioxidant, a viscosity controlling agent, an ultraviolet ray absorbent and the like. In the case where the inorganic material is used, the layer may be formed by a dry process, such as a resistance heating vapor deposition method, an electron beam vapor deposition method, a reactive vapor deposition method, an ion plating method and a sputtering method.

The interlayer 105 as an electron blocking layer may be accumulated between the light emitting layer 106 and the hole transporting layer 104, thereby enhancing the light emitting life of the device. In the device having the top emission structure, the interlayer may be accumulated after forming the hole transporting layer 104. The interlayer is generally formed to cover the hole transporting layer 104, and may be patterned depending on necessity.

Examples of the material for the interlayer 105 include, as organic materials, polymers having aromatic amine, such as polyvinylcarbazole and a derivative thereof, a polyarylene derivative having aromatic amine on side chain or main chain thereof, an arylamine derivative and a triphenyldiamine derivative. Examples thereof also include, as inorganic materials, inorganic compounds containing at least one of transition metal oxides, such as Cu₂O, Cr₂O₃, Mn₂O₃, NiO, CoO, Pr₂O₃, Ag₂O, MoO₂, ZnO, TiO₂, V₂O₅, Nb₂O₅, Ta₂O₅, MoO₃, WO₃ and MnO₂, nitrides thereof, and sulfides thereof. The invention is not limited to these compounds.

The organic material may be dissolved or stably dispersed in a solvent to form an organic interlayer ink. Examples of the solvent for dissolving or dispersing the organic interlayer material include single solvents of toluene, xylene, acetone, anisole, methyl ethyl ketone, methyl isobutyl ketone and cyclohexanone, and mixed solvents thereof. Among these, an aromatic organic solvent, such as toluene, xylene and anisole, is preferred from the standpoint of the solubility of the organic interlayer material. The organic interlayer ink may contain a surfactant, an antioxidant, a viscosity controlling agent, an ultraviolet ray absorbent and the like depending on necessity.

As the material for the interlayer 105, a material having a work function that is equivalent to or higher than that of the hole transporting layer 104 is preferably selected, and a material having a work function that is equivalent to or lower than that of the organic light emitting layer 106 is more preferred. This is because an unnecessary injection barrier is prevented from occurring on injecting carriers from the hole transporting layer 104 to the organic light emitting layer 106. Furthermore, for confinement of charges that have not contribute to the light emission from the organic light emitting layer 106, the band gap is preferably 3.0 eV or more, and more preferably 3.5 eV or more.

Examples of the forming method of the interlayer 105 include known film forming methods, for example, a dry film forming method, such as a resistance heating vapor deposition method, an electron beam vapor deposition method, a reactive vapor deposition method, an ion plating method and a sputtering method, and a wet film forming method, such as an ink jet printing method, a relief printing method, a gravure printing method and a screen printing method, which may be selected depending on the material used, and the invention is not limited thereto.

The light emitting layer 106 in the embodiment of the invention recombines electrons and holes injected through application of a voltage between the electrodes 102 and 107 and emits light through the recombination. The light thus emitted is radiated to the outside through the side of the light permeable electrode. In the case where different types of the light emitting layers 106 are formed for the respective pixels, for example, the light emitting layers 106R, 136G and 1063 for RGB full color are formed in a pattern form at the pixel positions on the first electrode 102.

In the invention, a mixed ink formed of two kinds of a polymer compound A (having a carrier mobility μA) and a polymer compound B (having a carrier mobility μB) having different carrier mobilities (μ) is used in the light emitting layer 106. The mixed ink may be used in all the light emitting layers 106R, 106G and 106B, and may be used in only one kind thereof.

Examples of the materials for the polymer compound A and the polymer compound B used in the light emitting layer 106 include materials obtained by dissolving a light emitting colorant, such as a coumarin series, a perylene series, a pyran series, an anthrone series, a porphyrin series, a quinacridone series, an N,N′-dialkyl-substituted quinacridone series, a naphthalimide series and an N,N′-diaryl-substituted pyrrolopyrrole series, in a polymer, such as polystyrene, poiymethyl methacrylate and polyvinylcarbazole. A dendrimer material and a polymer light emitting material, such as a PV series, a PAF series and a poly-p-phenylene series, may also be used. Preferred examples thereof include such a material that is soluble in water or a solvent and can be formed into a solution.

Furthermore, the materials shown as the material for the interlayer 105, for example, polymers having aromatic amine, such as polyvinylcarbazole and a derivative thereof, a polyarylene derivative having aromatic amine on side chain or main chain thereof, an arylamine derivative and a triphenyldiamine derivative, may be used as the material for the polymer compound A and the polymer compound B.

The material for the light emitting layer 106 may be dissolved or stably dispersed in a solvent to form an organic light emitting ink. Examples of the solvent for dissolving or dispersing the organic light emitting material include single solvents of toluene, xylene, acetone, anisole, methyl ethyl ketone, methyl isobutyl ketone and cyclohexanone, and mixed solvents thereof. Among these, an aromatic organic solvent, such as toluene, xylene and anisole, is preferred from the standpoint of the solubility and dispersibility of the organic light emitting material. The organic light emitting ink may contain a surfactant, an antioxidant, a viscosity controlling agent, an ultraviolet ray absorbent and the like depending on necessity.

The mixed ink may be formed in such a manner that the polymer compound A and the polymer compound B are mixed and then dissolved or dispersed in the solvent to form an ink, or the compounds may be separately formed into inks, which may be then mixed.

The respective light emitting layers 106 may be formed by a printing method, such as a screen printing method and an ink jet printing method. On forming by a printing method, the light emitting material may be dissolved in an organic solvent, water or a mixed solvent thereof to form an ink.

The electron injection layer is a layer that has a function of transporting electrons from the cathode (the second electrode 107J, and the electron transporting layer is a layer that, has a function of transporting electrons to the light emitting layer 106. These layers may have both the electron injection function and the electron transporting function in some cases, and may be referred to as one of or both of the names depending on the extent of the functions. Examples of the material constituting the electron injection layer or the electron transporting layer include a nitro-substituted fluorene, such as 1,2,4-triazole derivative (TAZ), and a diphenylketone derivative.

A second electrode (counter electrode) 107 of the embodiment of the invention is then formed on the light emitting medium layer 109. In the case of the active matrix driven organic EL device, the second electrode 107 is formed over the entire surface of the display region. As a specific example of the material for the second electrode 107, an elementary metal substance, such as Mg, Al and Yb, may be used, and Al and Cu having high stability and elect reconductivity may also be used by accumulating with Li or a compound, such as lithium oxide or lithium fluoride, in a thickness of approximately 1 nm disposed at the interface in contact with the light emitting medium layer 109.

For achieving both the electron injection efficiency and the stability, an alloy system containing at least one kind of a metal having a low work function, such as Li, Mg, Ca, Sr, La, Ce, Er, Eu, Sc, Y and Yb, and a stable metal element, such as Ag, Al and Cu. Specifically, alloys, such as MgAg, AlLi and CuLi, may be used. A transparent electroconductive film, for example, a metal complex oxide, such as ITO (indium tin complex oxide), IZO (indium zinc complex oxide) and AZO (zinc aluminum complex oxide), may be used.

The second electrode 107 in the top emission structure has necessarily light permeability in the visible light wavelength range for transmitting the display light emitted from the light emitting medium layer 109. The thickness thereof is preferably 20 nm or less for the elementary metal substance, such as Mg, Al and Yb, and more preferably from 2 to 7 nm. The transparent electroconductive film may be preferably used with a thickness controlled to achieve an average light transmittance of 85% or more over the visible light wavelength range.

Examples of the forming method of the second electrode 107 include known film forming methods, for example, a dry film forming method, such as a resistance heating vapor deposition method, an electron beam vapor deposition method, a reactive vapor deposition method, an ion plating method and a sputtering method, and a wet film forming method, such as an ink jet printing method, a gravure printing method and a screen printing method, which may be selected depending on the material used, and the invention is not limited thereto.

The sealing member 208 is adhered to the peripheral portion of the substrate 101 having formed thereon, for example, the first electrode 102, the partition wall 203, the light emitting medium layer 109 and the second electrode 107, thereby sealing them. At this time, in the top emission structure, the sealing member 208 necessarily has light permeability in the visible light wavelength range for taking out the emitted display light from the light emitting medium layer 109 through the sealing member 208 disposed on the opposite side of the substrate 101. The light permeability thereof is preferably 85% or more in terms of the average light transmittance over the visible light wavelength range.

The sealing member 208 may be a sealing cap 206 which is a glass cap, a metal cap, or the like having a concave space as shown in FIG. 1, in which the sealing cap 206 is applied to the substrate 101 having formed thereon, for example, the first electrode 102, the partition wall 203, the light emitting medium layer 109 and the second electrode 107, with the concave space being disposed above the first electrode 102, the light emitting medium layer 109 and the second electrode 107, and the sealing cap 206 and the substrate 101 are adhered to each other at the peripheral portion thereof, thereby sealing them. A moisture absorbent is disposed in the concave space, which is then sealed under an inert gas atmosphere, such as nitrogen gas, thereby preventing the device from being deteriorated by moisture, gases and the like.

The sealing with the sealing member 208 may be performed in such a manner as shown in FIG. 2 that a sealing material 209 and a resin layer 210 provided thereon are applied to the substrate 101 having formed thereon, for example, the first electrode 102, the partition wall 203, the light emitting medium layer 109 and the second electrode 107, and the sealing material is adhered to the substrate with the resin layer 210.

The material for the sealing material 209 herein is necessarily a material having low permeability to moisture and oxygen. Examples of the material include ceramics, such as alumina, silicon nitride and boron nitride, glass, such as non-alkali glass and alkali glass, quartz, and a moisture resistant film. Examples of the moisture resistant film include a film having a plastic substrate having on both surface thereof. SiOx formed by a CVD method, and a polymer film containing a film having low light permeability and a film having water absorbing property or having coated thereon a water absorbing agent, and the moisture permeability of the moisture resistant film is preferably (1×10⁻⁶ g/m²)/day or less.

Examples of the resin layer 210 include a photocurable adhesive resin, a thermosetting adhesive resin and a two-component curable adhesive resin, which may contain an epoxy resin, an acrylic resin, a silicone resin and the like, a thermoplastic resin, such as an acrylic resin, e.g., an ethylene-ethyl acrylate (EEA) polymer, a vinyl resin, e.g., an ethylene-vinyl acetate (EVA) polymer, polyamide, and synthetic rubber, and a thermoplastic adhesive resin, such as acid-modified products of polyethylene and polypropylene. Examples of the method for forming the resin layer 210 on the sealing material 209 include a solvent solution method, an extrusion, lamination method, a hot-melt method, a calender method, a nozzle application method, a screen printing method, a vacuum lamination method and a heat roll lamination method. A material having moisture absorbing property or oxygen absorbing property may be contained depending on necessity. The thickness of the resin layer 210 formed on the sealing material 209 may be arbitrarily determined depending on the size and shape of the organic EL device to be sealed, and is preferably approximately from 5 to 500 μm. When the thickness is 5 μm or less, the adhesion force may be disadvantageously decreased. When it exceeds 500 μm, the sealing property may be disadvantageously decreased.

The adhesion operation of the substrate 101 having formed thereon the first electrode 102, the partition wall 203, the light emitting medium layer 109 and the second electrode 107 with the sealing member 208 may be performed in a sealing chamber. In the case where the sealing member 208 has she two-layer structure including the sealing material 209 and one resin layer 210, and a thermoplastic resin is used as the resin layer 210, the adhesion operation is preferably performed only by compression adhesion with heated rolls. In the case where a thermosetting adhesive resin is used, the adhesion operation is preferably performed by compression adhesion with heated rolls, and then the assembly is preferably heat-cured at the curing temperature. In the case where a photocurable adhesive resin is used, the adhesion operation is preferably performed by compression adhesion with rolls, and then the assembly may be cured by irradiating with light. While the resin layer 210 is formed on the sealing material 209 in this embodiment, it is possible that the resin layer 210 is formed on the substrate 101, which is then adhered to the sealing material 209.

Before sealing with the sealing material 209 or instead thereof, for example, a sealing member 208 of an inorganic thin film, such as a silicon nitride film, may be formed as a passivation film by a dry process, such as an EB vapor deposition method or a CVD method, on the substrate 101 for sealing, and the combination use thereof may be employed. The thickness of the passivation film may be from 100 to 500 nm, and preferably from 150 to 300 nm, while it varies depending on the moisture permeability and the moisture transmittance of the material. When the thickness is less than 100 nm, she covering property and the flatness may be disadvantageously decreased. When it exceeds 500 nm, the film forming time may be prolonged to deteriorate disadvantageously the productivity, and cracking is disadvantageously liable to occur. In the top emission structure, the light permeability of the passivation film is necessarily considered in addition to these characteristics, and the light permeability thereof is preferably 70% or more in terms of an average over the visible light wavelength range.

### EXAMPLE

Examples of the organic thin film electroluminescence display equipment of the invention will be described below, but the invention is not limited to the examples.

### Example 1

On a glass substrate having a diagonal length of 1.8 inch as a light permeable substrate, an ITO (indium tin oxide) thin film was formed by a sputtering method, and the ITO film was patterned by a photolithography method and an etching method with an acid solution, thereby forming pixel electrodes. The line pattern of the pixel electrodes was a line width of 136 μm and a space of 30 μm, in which 192 lines were formed within a square of approximately 32 mm.

A partition wall was then formed in the following manner. A positive photosensitive polyimide (Photoneece DL-1000, produced by Toray Industries, Inc.) was spin-coated over the entire surface of the glass substrate having the pixel electrodes formed thereon. The condition of spin coating was rotation at 150 rpm for 5 seconds and then rotation at 500 rpm for 20 seconds per one time of coating, and the height of the partition wall was 1.5 μm. The photosensitive material coated on the entire surface was subjected to exposure and development by a photolithography method, thereby forming a partition wall having a line pattern between the pixel electrodes. The partition wall was then baked in an oven at 230° C. for 30 minutes.

As a surface treatment for ITO, the glass substrate having the partition wall formed was irradiated with an ultraviolet ray for 3 minutes with an UV/O₃ rinsing equipment, produced by Ore Manufacturing Co., Ltd. The work function of ITO was changed from 4.8 eV before irradiation to 5.3 eV.

A hole transporting layer was then formed. Molybdenum oxide as an inorganic material was formed into a film of 50 nm by a sputtering method over the entire display region. The patterning was performed with a metal mask having an opening of 120 mm×300 mm.

An organic light emitting ink A containing a polyphenylene vinylene derivative A, which was an organic light emitting material having a hole mobility of 1.0×10⁻³ (cm²/Vs) and an energy gap of 2.8 (eV), dissolved in toluene to a concentration of 1%, and an organic light emitting ink B containing a polyphenylene vinylene derivative B, which was an organic light emitting material having a hole mobility of 2.0×10⁻⁵ (cm²/Vs) and an energy gap of 3.0 (eV), dissolved in toluene to a concentration of 1% were prepared, and the ink A and the ink B were mixed at a weight ratio of 95/5 to prepare a mixed ink I.

A light emitting layer was printed by a relief printing method immediately on the pixel electrodes surrounded by the partition wall according to the line pattern thereof. The thickness of the light emitting layer after printing and drying was 100 nm.

A cathode layer formed of Ca and Al was formed thereon through mask vapor deposition by a resistance heating vapor deposition method in a line pattern that is perpendicular to the line pattern of the pixel electrodes. Finally, the organic EL assembly was sealed with a glass cap and an adhesive for protecting from external oxygen and moisture, thereby producing an organic EL display panel.

The resulting organic EL display panel had, in the peripheral portion of the display part, lead electrodes on the anode side connected to the respective pixel electrodes and lead electrodes on the cathode side, and an electric power source was connected to the electrodes, thereby confirming lightening and display of the resulting organic EL display panel.

On driving the resulting organic EL display panel, it exhibited a luminance of 500 cd/cm² and a CIE chromaticity of x=0.31 and y=0.63 at a driving voltage of 7 V, and the service life at an initial luminance of 1,000 cd/m² was 300 hours.

### Example 2

In Example 2, the organic light emitting ink A and the organic light emitting ink B were mixed at a weight ratio of 80/20 to prepare a mixed ink II. A light emitting layer was printed by a relief printing method immediately on the pixel electrodes surrounded by the partition wall according to the line pattern thereof. The thickness of the light emitting layer after printing and drying was 100 nm. The other conditions were the same as in Example 1. On driving the resulting organic EL display panel, it exhibited a luminance of 600 cd/cm² and a CIE chromaticity of x=0.31 and y=0.63 at a driving voltage of 7 V, and the service life at an initial luminance of 1,000 cd/m² was 250 hours.

### Comparative Example 1

In Comparative Example 1, the organic light emitting ink A and the organic light emitting ink B were mixed at a weight ratio of 50/50 to prepare a mixed ink III. A light emitting layer was printed by a relief printing method immediately on the pixel electrodes surrounded by the partition wall according to the line pattern thereof. The thickness of the light emitting layer after printing and drying was 100 nm. The other conditions were the same as in Example 1. On driving the resulting organic EL display panel, it exhibited a luminance of 1,000 cd/cm² and a CIE chromaticity of x=0.31 and y=0.63 at a driving voltage of 7 V, but the service life at an initial luminance of 1,000 cd/m² was lowered to 100 hours.

### Comparative Example 2

In Comparative Example 2, the organic light emitting ink A and an organic light emitting ink C containing a polyphenylene vinylene derivative C, which was an organic light emitting material having a hole mobility of 5.0×10⁻³ (cm²/Vs) and an energy gap of 2.9 (eV), dissolved in toluene to a concentration of 1% were produced, and the organic light emitting ink A and the organic light emitting ink C were mixed at a weight ratio of 95/5 to prepare a mixed ink IV. A light emitting layer was printed by a relief printing method immediately on the pixel electrodes surrounded by the partition wall according to the line pattern thereof. The thickness of the light emitting layer after printing and drying was 100 nm. The other conditions were the same as in Example 1. On driving the resulting organic EL display panel, it exhibited a luminance of 350 cd/cm² and a CIE chromaticity of x=0.31 and y=0.63 at a driving voltage of 7 V, and the service life at an initial luminance of 1,000 cd/m² was 300 hours.

### Comparative Example 3

In Comparative Example 3, the organic light emitting ink A and an organic light emitting ink D containing a polyphenylene vinylene derivative D, which was an organic light emitting material having a hole mobility of 2.0×10⁻³ (cm²/Vs) and an energy gap of 2.6 (eV), dissolved in toluene to a concentration of 1% were produced, and the organic light emitting ink A and the organic light emitting ink D were mixed at a weight ratio of 95/5 to prepare a mixed ink V. A light emitting layer was printed by a relief printing method immediately on the pixel electrodes surrounded by the partition wall according to the line pattern thereof. The thickness of the light emitting layer after printing and drying was 100 nm. The other conditions were the same as in Example 1. On driving the resulting organic EL display panel, it exhibited a luminance of 530 cd/cm² at a driving voltage of 7 V, but the CIE chromaticity was changed to x=0.38 and y=0.58. The service life at an initial luminance of 1,000 cd/m² was 280 hours.

The conditions and the evaluation results of the examples are shown in Table 1.

TABLE 1

| | | Hole | | | Hole | | | | Luminance |
|---|---|---|---|---|---|---|---|---|---|
| | | mobility | | | mobility | | Weight ratio | | (cd/cm²) on 7 V |
| | Ink (X) | (cm²/Vs) | Eg (eV) | Ink (Y) | (cm²/Vs) | Eg (eV) | Ink (X) | Ink (Y) | driving |
| Mixed ink I | organic light emitting | 1.00 × 10⁻³ | 2.8 | organic light emitting | 2.00 × 10⁻⁵ | 3.0 | 95 | 5 | 500 |
| | ink A | | | ink B | | | | | |
| Mixed ink II | organic light emitting | 1.00 × 10⁻³ | 2.8 | organic light emitting | 2.00 × 10⁻⁵ | 3.0 | 80 | 20 | 600 |
| | ink A | | | ink B | | | | | |
| Mixed ink III | organic light emitting | 1.00 × 10⁻³ | 2.8 | organic light emitting | 2.00 × 10⁻⁵ | 3.0 | 50 | 50 | 1,000 |
| | ink A | | | ink B | | | | | |
| Mixed ink IV | organic light emitting | 1.00 × 10⁻³ | 2.8 | organic light emitting | 5.00 × 10⁻³ | 2.9 | 95 | 5 | 350 |
| | ink A | | | ink C | | | | | |
| Mixed ink V | organic light emitting | 1.00 × 10⁻³ | 2.8 | organic light emitting | 2.00 × 10⁻³ | 2.6 | 95 | 5 | 530 |
| | ink A | | | ink D | | | | | |

### DESCRIPTION OF SYMBOLS

101 substrate
102 first electrode
104 hole transporting layer (hole injection layer)
105 interlayer
106 light emitting layer
107 second electrode
107a light impermeable second electrode
107b light permeable second electrode
109 light emitting medium layer
200 display equipment
203 partition wall
206 sealing cap
208 sealing member
209 sealing material
210 resin layer
301 reflective layer

1. An organic electroluminescence device comprising a substrate having thereon:
a first electrode,
a light emitting medium layer containing at least a light emitting layer, and
a second electrode on the light emitting medium layer, at least one layer of the light emitting medium layer being formed with a mixed ink containing a first polymer compound and a second polymer compound that has a carrier mobility larger than that of the first polymer compound, the mixed ink having a weight ratio of the second polymer compound to the first polymer compound of 30% by weight or less, the mixed ink providing the device with a light emitting voltage that is lower than a case where the at least one layer of the light emitting medium layer is formed with an ink containing only the first polymer compound.

2. The organic electroluminescence device according no claim 1, wherein the second polymer compound has a hole mobility of more than 1.0×10⁻⁴ (cm²/Vs).

3. The organic electroluminescence device according to claim 2, wherein the second polymer compound has an energy gap that is larger than an energy gap of the first polymer compound.

4. The organic electroluminescence device according to claim 3, wherein the light emitting layer is formed with the mixed ink.
